(19) United States
(12) Patent Application Publication
(10) Pub. No.: US 2004/0183190 A1
(43) Pub. Date: Sep. 23, 2004

(54) Multi-chips stacked package

(75) Inventor: Sung-Fei Wang, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/747,131

(22) Filed: Dec. 30, 2003

(30) Foreign Application Priority Data
Mar. 21, 2003 (TW) 092106425

(51) Int. Cl. H01L 23/34

(52) U.S. Cl. 257/723

(57) ABSTRACT

A multi-chips stacked package mainly comprises a substrate, a first lower chip, a second lower chip, an upper chip, and a filled material. The substrate has an upper surface, and the first lower chip and the second lower chip are disposed on the upper surface of the substrate and electrically connected to the substrate. The filled material is disposed in and filled with a gap between the first lower chip and the second lower chip, and the upper chip is mounted on the first lower chip, the second lower chip and the top of the filled material. Moreover, the upper chip is electrically connected to the substrate through electrically conductive wires.

### BACKGROUND OF THE INVENTION

1. Field of Invention

This invention relates to a multi-chips stacked package. More particularly, the present invention is related to a multi-chips stacked package having a filled material for supporting a portion of the upper chip not supported by the lower chips so as to prevent the upper chip from being damaged and cracked in the operation of wire-bonding process.

2. Related Art

Recently, integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) package is commonly used in said assembly package and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Generally speaking, conventional MCM packages shall be a multi-chips side-by-side package or a multi-chips stacked package. As shown in FIG. 1, it illustrates a multi-chips stacked package and said stacked package is formed by disposing upper chips 12 and 13 on a lower chip 14 by wire-bonding and chip-stacking technology, electrically connecting the upper chips 12 and 13 to a substrate 16 respectively and electrically connecting the upper chips 12 and 13 with each other via electrically conductive wires 18. However, one of the peripheral sides of the upper chip 12 and one of the peripheral sides of the upper chip 13 overhangs the lower chip 14. Namely, the upper chip 12 is partially disposed on the lower chip 14 and overhangs over the lower chip 14. Similarly, the upper chip 13 is also partially disposed on the lower chip 14 and overhangs over the lower chip 14. Thus, the upper chips 12 and 13 will be damaged and cracked more easily in the operation of the wire-bonding process. Referring to FIG. 2, lower chips 22 and 23 are disposed on the substrate 26, and the upper chip 24 is mounted on the lower chips 22 and 23 simultaneously so that the upper chip 24 can be supported firmly by the lower chips 22 and 23 and the substrate 26, and can be prevented from being damaged and cracked.

As mentioned above, however, there are several disadvantages as following shown. When the lower chips 22 and 23 are adjacent to each other and connect each other, the lower chip 22 will be pressed against the lower chip 23 due to thermal expansion. Thus, in order to prevent the above-mentioned problem, the lower chips 22 and 23 shall be apart from each other in a distance. However, when the distance between the lower chips 22 and 23 is larger than 50 μm, the portion 242 of the lower surface of the of the upper chip 24 not supported by the lower chips 22 and 23 will be damaged easily in the performance of the wire-bonding process.

Therefore, providing another assembly package to solve the mentioned-above disadvantages is the most important task in this invention.

### SUMMARY OF THE INVENTION

In view of the above-mentioned problems, an objective of this invention is to provide a multi-chips stacked package to improve the reliability of the wire-bonding process and prevent the upper chip from being easily damaged. Therein, a filled material is filled with the gap between the lower chips so as to support a portion of the upper chip not supported by the lower chips and to prevent the upper chip and to solve the above-mentioned disadvantage.

To achieve the above-mentioned objective, a multi-chips stacked package is provided, wherein the multi-chips stacked package mainly comprises a substrate, an upper chip, a first lower chip, a second lower chip and a filled material. Therein, the substrate has an upper surface for disposing the first lower chip and the second lower chip, and the first lower chip and the second lower chip are electrically connected to the substrate respectively. Said filled material is filled with a gap between the first lower chip and the second lower chip, and the upper chip is mounted on the upper chip and the filled material simultaneously and electrically connected to the substrate via a plurality of electrically conductive wires.

As mentioned above, the filled material may be a non-electrically conductive epoxy or an underfill. Specifically, the underfill has a good stiffness due to epoxy and filler formed therein, so the underfill can support the portion of the upper chip not supported by the lower chips when the upper chip is wire bonded to the substrate. Thus, the upper chip can be prevented from damaging.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips stacked package;

FIG. 2 is a cross-sectional view of another conventional multi-chips stacked package;

FIG. 3 is a cross-sectional view of another conventional multi-chips stacked package;

FIG. 4 is a cross-sectional view of a multi-chips stacked package according to the first embodiment; and

FIG. 5 is a cross-sectional view of a multi-chips stacked package according to the second embodiment.

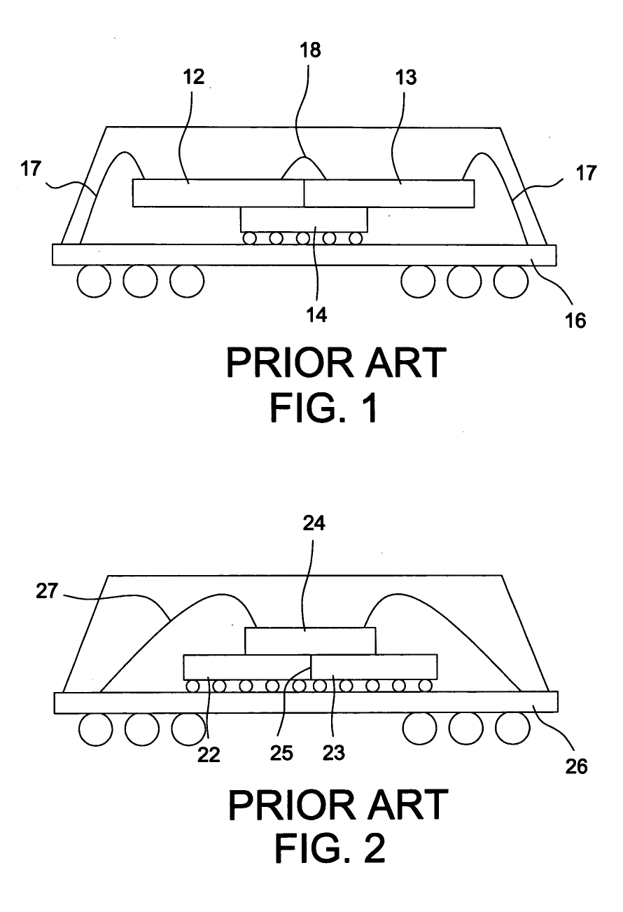

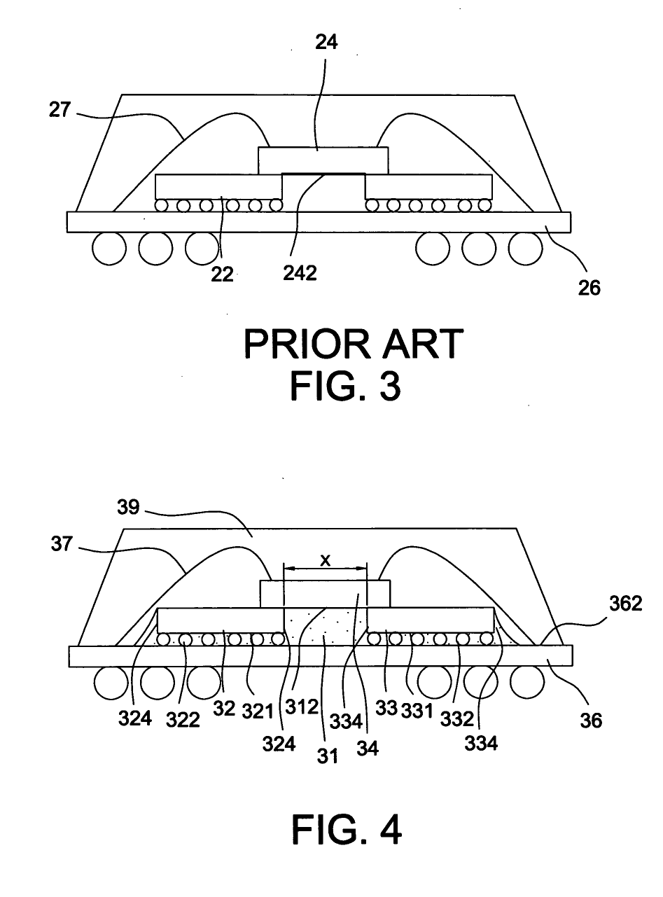

### DETAILED DESCRIPTION OF THE INVENTION

The multi-chips stacked package according to the preferred embodiment of this invention will be described herein below with reference to the accompanying drawings, wherein the same reference numbers refer to the same elements.

In accordance with a first preferred embodiment as shown in FIG. 4, there is provided a multi-chips stacked package. The multi-chips stacked package mainly comprises a filled material 31, a first lower chip 32, a second lower chip 33, an upper chip 34 and a substrate 36. Therein, the substrate 36 has an upper surface 362, and the first lower chip 32 and the second lower chip 33 are disposed on the upper surface 362 of the substrate 36 and electrically connected to the substrate 36 via electrically conductive bumps 322 and 332 respectively. In addition, the filled material 31 is filled with the gap between the first lower chip 32 and the second lower chip 33 and at least covers the first side 324 of the first lower chip 32 and the second side 334 of the second chip 33. Consequently, the top 312 of the filled material 31 is substantially a flat plane and coplanar to a first back surface of the first lower chip 32 and a second back surface of the second lower chip 33. Moreover, the upper chip 33 is disposed on the first lower chip 32, the second lower chip 33 and the filled material 31, and the top 312 of the filled material 31 is attached to the upper chip 34 securely. In addition, another adhesive may be disposed on the top 312 of the filled material so as to connect the filled material 31 and the upper chip 34. Besides, the upper chip 34 is also electrically connected to the substrate 36 via electrically conductive wires 37. In addition, there is an encapsulation 39 provided in said package to enclose the filled material 31, the first lower chip 32, the second lower chip 33, the upper chip 34 and the electrically conductive wires 37.

Besides, as mentioned above, the first lower chip 32 and the second lower chip 33 are electrically connected to the substrate 36 via first bumps 322 formed on the first active surface 321 and second bumps 332 formed on the second active surface 331; and the filled material 31 encloses the first bumps 322 and the second bumps 332. Similarly, an encapsulation 39 is further provided to enclose the first lower chip 32, the second lower chip 33, the upper chip 34 and the filled material 31, and to cover the substrate 36.

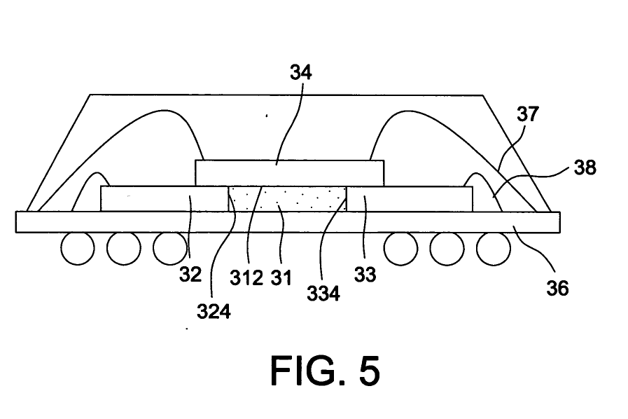

Furthermore, as shown in FIG. 5, it illustrates a second embodiment according to this invention. The first lower chip 32 and the second lower chip 33 are disposed on the substrate 36 and electrically connected to the substrate 36 respectively via a plurality wires 38, and a filled material 31 is filled with a gap between the first lower chip 32 and the second lower chip 33 so as to cover the first side 324 of the first lower chip 32 and the second side 334 of the second lower chip 33 and form a top 312 of the filled material 31. Therein, the top 312 of the filled material 31 is coplanar to the first active surface of the first lower chip 32 and the second active surface of the second lower chip 33. Moreover, the upper chip 34 is disposed on the top 312 of the filled material 31, the first lower chip 32, and the second lower chip 33. In addition, the upper chip 34 is electrically connected to the substrate 36 via a plurality of wires 37. It should be noted that the substrate as mentioned above may be replaced by a lead-frame. Accordingly, said package can be mounted to a motherboard by surface mount technology (SMT) without any further solder balls formed on the lower surface of the lead-frame.

As mentioned above, the filled material as mentioned above can be an underfill or other non-electrically conductive epoxy. Specifically, the underfill is made of epoxy and filler, so the underfill has a good stiffness to support the portion of the upper chip not supported by the lower chips when the upper chip is wire bonded to the substrate. Thus, the upper chip can be prevented from damaging. It should be noted that the reference numeral of each element shown in FIG. 5 are corresponding the reference one provided in FIG. 4.

In summary, the upper chip is disposed on the first lower chip, the second lower chip and the top of the filled material. Therein, the filled material can support a portion of the upper chip not supported by the first lower chip and the second lower chip. Accordingly, when the first lower chip takes apart from the second chip with a distance “X” more than 50 μm as shown in FIG. 4, the filled material can prevent the upper chip from damaging in the performance of the upper chip wire-bonding to the substrate due to the bonding force transmitting to the filled material.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips stacked package, comprising:
a substrate having an upper surface and a lower surface;
a first lower chip disposed on the upper surface of the substrate and electrically connected to the substrate;
a second lower chip disposed on the upper surface of the substrate and electrically connected to the substrate, wherein the second lower chip is parallel to the first lower chip and apart from the first lower chip to form a gap;
a filled material disposed in the gap so as to connect the first lower chip and the second lower chip; and
an upper chip electrically connected to the substrate and disposed on the first lower chip, the second lower chip and the filled material.

2. The multi-chips stacked package of claim 1, wherein the first lower chip further comprises a first active surface, a first back surface and a first bump, and the first bump is formed on the first active surface and electrically connected to the substrate.

3. The multi-chips stacked package of claim 2, wherein the filled material further comprises a top, and the top is coplanar to the first back surface of the first lower chip.

4. The multi-chips stacked package of claim 2, wherein the second lower chip further comprises a second active surface, a second back surface and a second bump, and the second bump is formed on the second active surface and electrically connected to the substrate.

5. The multi-chips stacked package of claim 4, wherein the top of the filled material is coplanar to the second back surface of the second chip.

6. The multi-chips stacked package of claim 1, wherein the filled material further comprises a top, and the top of the filled material connects to the upper chip.

7. The multi-chips stacked package of claim 1, further comprising an adhesive interposed between a top of the filled material and the upper chip.

8. The multi-chips stacked package of claim 1, wherein the filled material further comprises a top and the top is substantially a flat plane.

9. The multi-chips stacked package of claim 2, wherein the filled material encloses the first bump.

10. The multi-chips stacked package of claim 1, wherein the filled material covers a first side of the first lower chip.

11. The multi-chips stacked package of claim 1, wherein the filled material covers a second side of the second lower chip.

12. The multi-chips stacked package of claim 1, wherein the upper chip is electrically connected to the substrate via a plurality of wires.

13. The multi-chips stacked package of claim 1, further comprising an encapsulation covering the first lower chip, the second lower chip, the upper chip, the filled material and the upper surface of the substrate.

14. The multi-chips stacked package of claim 1, wherein a first side of the first lower chip is apart from a second side of the second lower chip with a distance.

15. The multi-chips stacked package of claim 14, wherein the distance is larger than 50 μm.

16. The multi-chips stacked package of claim 1, wherein the filled material is an underfill.

17. The multi-chips stacked package of claim 1, wherein the filled material is a dielectric material.

18. The multi-chips stacked package of claim 1, further comprising a plurality of solder balls formed on the lower surface of the substrate.
